(19) United States
(12) Patent Application Publication
(10) Pub. No.: US 2014/0126146 A1
(43) Pub. Date: May 8, 2014

(54) AIR DUCT

(71) Applicants: Hon Hai Precision Industry Co., Ltd., New Taipei (TW); Hong Fu Jin Precision Industry (ShenZhen) Co., Ltd., Shenzhen (CN)

(72) Inventors: YU HAN, Shenzhen (CN); AN-GANG LIANG, Shenzhen (CN)

(21) Appl. No.: 13/918,996

(22) Filed: Jun. 17, 2013

(30) Foreign Application Priority Data
Nov. 8, 2012 (CN) 2012104430349

(51) Int. Cl. H05K 7/20; H05K 5/02

(52) U.S. Cl. CPC H05K 7/20145; H05K 5/0213
USPC 361/695; 165/139

(57) ABSTRACT

An air duct is made to be set on a motherboard in a variety of different locations and aspects, for covering a number of electronic components in the most efficient way. The air duct includes a top wall, two sidewalls extending down from opposite sides of the top wall, and a frame mounted to a first end of the top wall. The frame defines a receiving space for receiving a fan, the manner of installation of the air duct permits more than one installation location, to allow for new or differently-located components on the motherboard.

### BACKGROUND

1. Technical Field

The present disclosure relates to an air duct.

2. Description of Related Art

An air duct in a computer enclosure may be aligned with a fan, for dissipating heat generated by heat-generation elements, such as central processing units arranged on a motherboard. However, when the heat-generation elements are arranged at different positions of the motherboard, the air duct and the fan both need to be moved to new positions suitable for the heat-generation elements, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an air duct, together with an enclosure and two fans.

FIG. 2 is an inverted view of the air duct of FIG. 1.

FIG. 3 and FIG. 4 are assembled, isometric views of the air duct of FIG. 1, but showing two different states of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

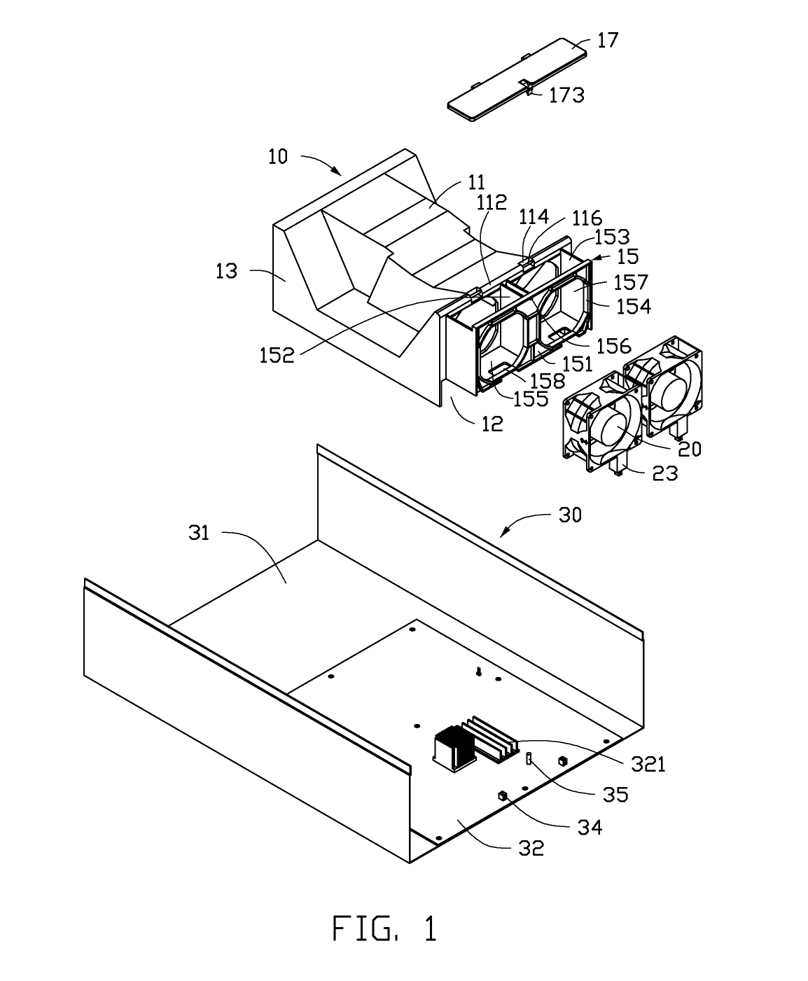

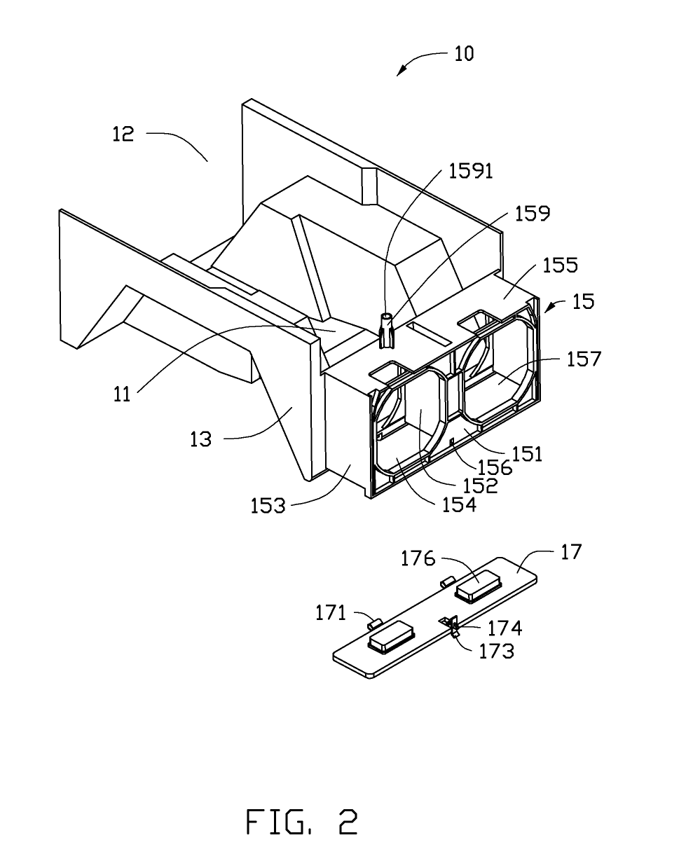

Referring to FIGS. 1 and 2, an embodiment of an air duct 10 is mounted in an enclosure 30 of an electronic device, such as a computer, with two fans 20. The air duct 10 includes a top wall 11, two sidewalls 13 extending down from opposite sides of the top wall 11, a frame 15 mounted to a first end of the top wall 11, and a cover 17.

The top wall 11 and the sidewalls 13 together bound an air channel 12. The frame 15 blocks one end of the air channel 12. A raised portion 112 is formed on the first end of the top wall 11, adjacent to the frame 15. The raised portion 112 defines two spaced recessed portions 114. A pivot pole 116 is defined in each recessed portion 114.

The frame 15 is substantially rectangular, and includes two side plates 151 opposite to each other, two end plates 153 connected between ends of the side plates 151, and a bottom plate 155 connecting the bottom sides of the side plates 151 and the end plates 153. One of the side plates 151 is connected to the top wall 11 and the sidewalls 13. Two dividing plates 152 are arranged between the side plates 151. A receiving space 157 is bounded by each end plate 153 and an adjacent dividing plate 152. Each side plate 151 defines two vents 154 aligning with the receiving spaces 157. A locking slot 156 is defined in an upper portion of one of the side plates 151 away from the raised portion 112. Two through holes 158 are defined in the bottom plate 155 and communicate with the receiving spaces 157. A guiding pole 159, defining a guiding hole 1591, extends down from the bottom plate 155.

The cover 17 is substantially rectangular, and includes two pivoting portions 171 with C-shaped cross-section and formed at a first side of the cover 17, and a resilient hook 173 formed at a second side of the cover 17 opposite to the first side. A hooking portion 174 is formed on a middle of the hook 173. Two resilient pads 176 are set on a middle of a bottom of the cover 17.

In this embodiment, the fans 20 are hot plug fans. Each fan 20 includes a connector 23 at the base.

The enclosure 30 includes a bottom wall 31 and a motherboard 32 set on the bottom wall 31. A plurality of electronic components 321, such as expansion cards, is set on the motherboard 32. Two sockets 34 and a tab 35 are arranged on the motherboard 32, adjacent to the electronic components 321.

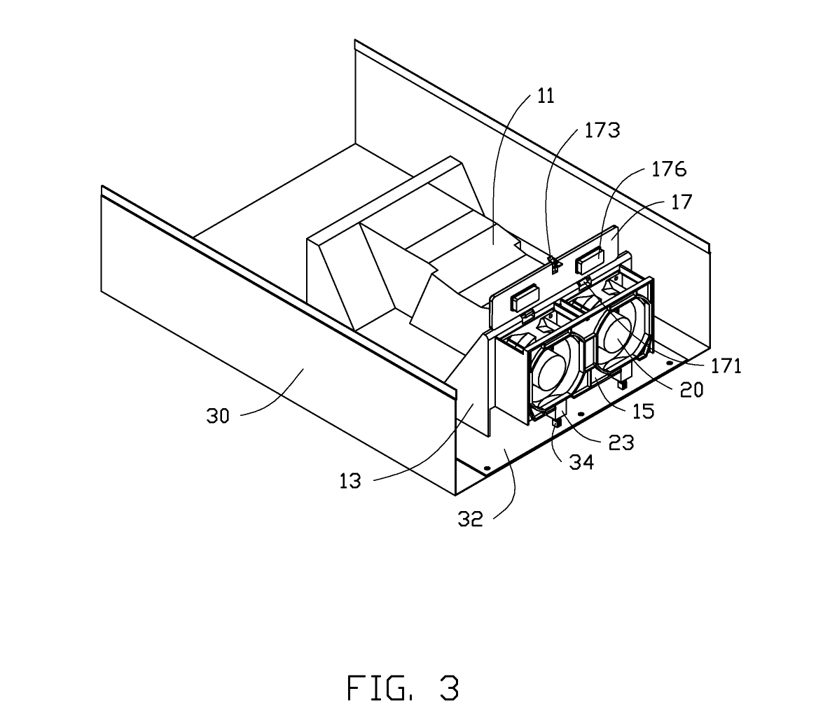

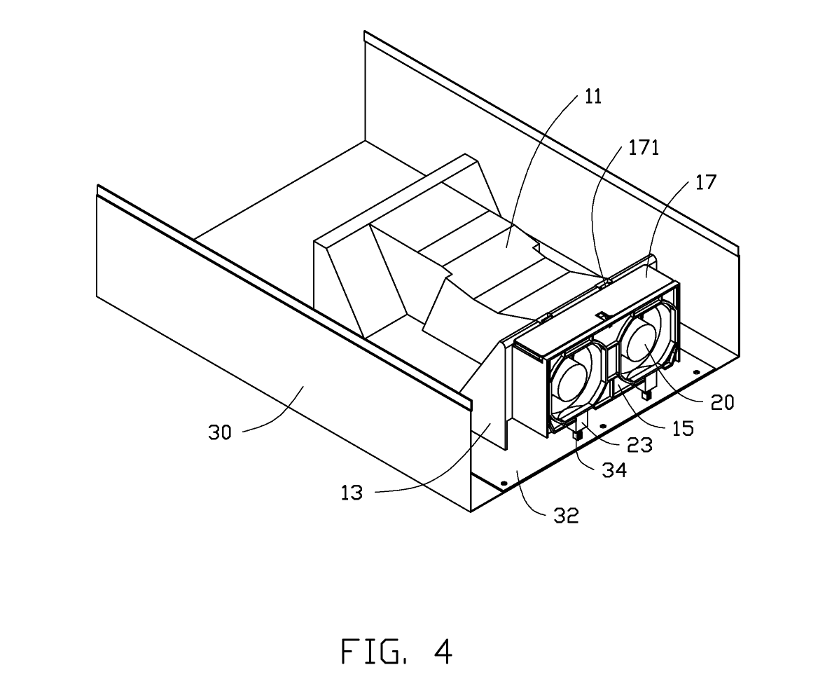

Referring to FIG. 3 and FIG. 4, the pivoting portions 171 are pivotably attached to the pivot poles 116, to pivotably connect the cover 17 to the top wall 11.

The air duct 10 is supported on the motherboard 32, with the tab 35 inserted into the guiding hole 1591. The air duct 10 can be fixed to the motherboard 32 by screws. The electronic components 321 are received in the air duct 10. The sockets 34 align with the through holes 158.

When heat dissipation needs to be enhanced, the cover 17 is rotated up. One or two fans 20 are installed and plugged into the frame 15, to be received in the receiving spaces 157. The connectors 23 extend through the through holes 158 to be plugged into the sockets 34. The cover 17 is then rotated back, until the hooking portion 174 is locked to the locking slot 156. The resilient pads 176 abut against the fans 20, to retain and absorb vibration from the fans 20.

In another embodiment, the fans 20 can be released from the frame 15 to make the frame 15 redundant. The hooking portion 174 of the cover 17 is locked to the locking slot 156. Air can still flow into and through the air channel 12 through the vents 154.

It is believed that the present embodiments and their advantages will be understood from the foregoing description, and various changes may be made thereto without departing from the spirit and scope of the description or sacrificing all of their material advantages, the examples hereinbefore described merely being embodiments.

What is claimed is:

1. An air duct comprising:
a top wall;
two sidewalls extending down from opposite sides of the top wall; and
a frame mounted to a first end of the top wall for receiving at least one fan, wherein the frame comprises two side plates opposite to each other, each of the side plates defines at least one vent.

2. The air duct of claim 1, wherein the frame further comprises two end plates connected between corresponding ends of the side plates, and a bottom plate connected among bottoms of the side plates and the end plates.

3. The air duct of claim 2, further comprising a cover, wherein the cover is pivotably attached to the first end of the top wall, for covering a top of the frame.

4. The air duct of claim 3, wherein a raised portion is formed on the first end of the top wall, the raised portion defines two spaced recessed portions, a pivot pole is defined in each of the recessed portions, the cover comprises two pivoting portions formed at a first side of the cover and a hook formed at a second side of the cover, a locking slot is defined in a top portion of one of the side plates of the frame away from the raised portion, the pivoting portions are pivotably attached to the corresponding pivot poles, to pivotably connect the cover to the top wall, the hook is detachably locked to the locking slot.

5. The air duct of claim 4, wherein two resilient pads are set on a middle of a bottom of the cover.

6. The air duct of claim 2, wherein the frame further comprises two dividing plates arranged between the side plates, two receiving spaces are bounded by the end plates and the corresponding dividing plates, for receiving fans.

7. The air duct of claim 6, wherein two through holes are defined in the bottom plate and communicate with the receiving spaces.

8. An assembly comprising:
a motherboard comprising a plurality of electronic components and a socket set on the motherboard;
an air duct set on the motherboard and covering the plurality of electronic components, the air duct comprising a top wall, two sidewalls extending down from opposite sides of the top wall, and a frame mounted to a first end of the top wall, the frame defining a receiving space; and
at least one fan received in the receiving space.

9. The assembly of claim 8, wherein the frame comprises two side plates opposite to each other, each of the side plates defines at least one vent aligning with the at least one fan.

10. The assembly of claim 8, wherein the top wall and the sidewalls together bound an air channel receiving the plurality of electronic components, the frame blocks one end of the air channel.

11. The assembly of claim 8, wherein the frame further comprises two end plates connected between corresponding ends of the side plates, and a bottom plate connected among bottoms of the side plates and the end plates.

12. The assembly of claim 11, wherein a cover is pivotably attached to the first end of the top wall, for covering the frame.

13. The assembly of claim 12, wherein a raised portion is formed on the first end of the top wall, the raised portion defines two spaced recessed portions, a pivot pole is defined in each of the recessed portions, the cover comprises two pivoting portions formed at a first side of the cover and a hook formed at a second side of the cover, a locking slot is defined in a top portion of one of the side plates of the frame away from the raised portion, the pivoting portions are pivotably attached to the corresponding pivot poles, to pivotably connect the cover to the top wall, the hook is detachably locked to the locking slot.

14. The assembly of claim 13, wherein a resilient pad is set on a middle of the cover for abutting against the at least one fan.

15. The assembly of claim 11, wherein the at least one fan comprises a connector, a through hole is defined in the bottom plate and communicates with the receiving space, a socket is set on the motherboard adjacent to the plurality of electronic components, the connector of the at least one fan extends through the through hole to be plugged into the socket.

16. The assembly of claim 11, wherein a guiding pole extends down from the bottom plate, the guiding pole defines a guiding hole, a tab is formed on the motherboard adjacent to the plurality of electronic components, the tab is engaged in the guiding hole.
